(19) United States
(12) Patent Application Publication
(10) Pub. No.: US 2013/0001798 A1
(43) Pub. Date: Jan. 3, 2013

(54) SEMICONDUCTOR PACKAGE

(75) Inventor: YunSeok Choi, Hwaseong-si (KR)

(73) Assignee: SAMSUNG ELECTRONICS CO., LTD., Suwon-si (KR)

(21) Appl. No.: 13/534,544

(22) Filed: Jun. 27, 2012

(30) Foreign Application Priority Data
Jul. 1, 2011 (KR) 10-2011-0065615

(51) Int. Cl. H01L 23/498

(52) U.S. Cl. 257/774; 257/E23.067

(57) ABSTRACT

A semiconductor package having a first semiconductor device including an active surface and a non-active surface opposite to the active surface, and a second semiconductor device having an active surface facing the active surface of the first semiconductor device is provided. Connection terminals are provided on the active surface of the second semiconductor device and first through vias are provided in the first semiconductor device. External terminals providing electrical connection with an external device are provided. The connection terminals comprise center terminals overlapping with the active surface of the first semiconductor device and outer terminals around the center terminals. The center terminals are electrically connected to the external terminals through the first through via.

### CROSS-REFERENCE TO RELATED APPLICATIONS

This U.S. non-provisional patent application claims priority under 35 U.S.C. §119 to Korean Patent Application No. 10-2011-0065615, filed on Jul. 1, 2011, the entirety of which is incorporated by reference herein.

### BACKGROUND

The present disclosure herein relates to semiconductor packaging technology and, more particularly, to a semiconductor package including a plurality of stacked semiconductor devices.

Semiconductor devices are widely used in high performance electronic systems, and the capacity and/or speed of semiconductor devices increases at a rapid pace. Thus, research is carried out in order to integrate multifunctional circuits into ever smaller semiconductor devices and to improve the performance of semiconductor devices.

In order to improve the efficiency of integration and/or performance of operation of semiconductor devices, a semiconductor package including may include plurality of stacked semiconductor chips. For example, a multi-chip package may include a plurality of stacked semiconductor memory chips, and a system-in package (SIP) may include a logic chip having a logic circuit and a memory chip which are stacked.

A complete SIP system may be comprised of stacked semiconductor chips of different kinds included in one package. In order to miniaturize electronic products, an SIP may include many individual elements, performing various functions, in one package.

### SUMMARY

At least some example embodiments of inventive concepts relate to semiconductor packages realizing a system-in-package (SIP).

Example embodiments according to inventive concepts may also provide semiconductor packages with improved structural and/or electrical characteristics.

In at least one example embodiment, a semiconductor package may include a first semiconductor device including an active surface and a non-active surface opposite to the active surface, a second semiconductor device provided on the first semiconductor device and having an active surface facing the active surface of the first semiconductor device, connection terminals on the active surface of the second semiconductor device, first through vias in the first semiconductor device, and external terminals providing electrical connection with an external device. The connection terminals may include: center terminals overlapping with the active surface of the first semiconductor device and outer terminals around the center terminals. The center terminals may be electrically connected to the external terminals through the first through via.

In some embodiments, the outer terminals may be electrically connected to the external terminals not through the first through vias.

In other embodiments, the package may further include a package substrate between the first semiconductor device and the external terminals. In this case, the external terminals may be provided on a bottom surface of the package substrate.

In still other embodiments, the first semiconductor device may be provided in a recess region formed in an upper portion of the package substrate.

In yet other embodiments, the external terminals may include first external terminals provided on a bottom surface of the first semiconductor device to be connected to the first through vias, and second external terminals electrically connected to the outer terminals.

In yet still other embodiments, each of the second external terminals may be greater in volume than each of the first external terminals.

In further embodiments, the package may further include an interposer between the first semiconductor device and the second semiconductor device. The second external terminals may be provided on a bottom surface of the interposer.

In still further embodiments, the package may further include an interposer between the first semiconductor device and the second semiconductor device and second through vias penetrating the interposer. The outer terminals may be electrically connected to the external terminals through some of the second through vias and the center terminals may be electrically connected to the first through vias through others of the second through via.

In even further embodiments, the package may further include first terminals provided on a bottom surface of the first semiconductor device. Some of the first through vias may not be electrically connected to the first terminals.

In yet further embodiments, the active surface of the second semiconductor device may be wider than the active surface of the first semiconductor device.

In yet further embodiments, the center terminals may provide a power voltage or a ground voltage to the second semiconductor device from the external device.

In at least some example embodiments, a semiconductor package may include: a first semiconductor device, a second semiconductor device on the first semiconductor device, connection terminals provided on a bottom surface of the second semiconductor device, first through vias provided in the first semiconductor device, and external terminals providing electrical connection with an external device. Some of the connection terminals may be electrically connected to the first through vias and the others of the connection terminals may be electrically connected to the external terminals not through the first through vias.

In some embodiments, the semiconductor package may have an active surface on the first semiconductor device and an active surface on the second semiconductor device.

In some embodiments, an active surface of the first semiconductor device and an active surface of the second semiconductor device may face each other.

In some embodiments, the semiconductor package may have an interposer between the first and second semiconductor devices where the interposer may include second through vias and where some of the connection terminals may be electrically connected to the second through vias.

In other embodiments, the package may further include an interposer disposed between the first and second semiconductor devices and the interposer may include second through vias. The connection terminals may be electrically connected to the second through vias.

In still other embodiments, the first through vias may connect the connection terminals to the external terminals.

In yet other embodiments, some of the first through vias may electrically connect the connection terminals to the external terminals.

In other embodiments, an interposer may be disposed between the first and second semiconductor devices and the interposer may contain second through vias and some of the connection terminals may be electrically connected to the second through vias.

### BRIEF DESCRIPTION OF THE DRAWINGS

The inventive concepts will become more apparent in view of the attached drawings and accompanying detailed description.

FIG. 1 is a cross sectional view illustrating a semiconductor package according to example embodiments of inventive concepts;

FIG. 2 is a view illustrating a bottom surface of a second semiconductor device according to example embodiments of inventive concepts;

FIG. 3 is a cross sectional view illustrating a semiconductor package according to other example embodiments of inventive concepts;

FIG. 4 is a cross sectional view illustrating a semiconductor package according to still other example embodiments of inventive concepts;

FIG. 5 is a cross sectional view illustrating a semiconductor package according to yet other example embodiments of inventive concepts;

FIG. 6 is a view illustrating an example of package modules including a semiconductor package according to embodiments of inventive concepts; and

FIG. 7 is a schematic block diagram illustrating an example of electronic devices including a semiconductor package according to embodiments of inventive concepts.

### DETAILED DESCRIPTION OF EXAMPLE EMBODIMENTS

The inventive concepts will now be described more fully hereinafter with reference to the accompanying drawings, in which exemplary embodiments of inventive concepts are shown. The advantages and features of inventive concepts and methods of achieving them will be apparent from the following exemplary embodiments that will be described in more detail with reference to the accompanying drawings. It should be noted, however, that inventive concepts are not limited to the following exemplary embodiments, and may be implemented in various forms. Accordingly, the exemplary embodiments are provided only to disclose inventive concepts and let those skilled in the art know the category of inventive concepts. In the drawings, embodiments of inventive concepts are not limited to the specific examples provided herein and may be exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as ideal exemplary views of inventive concepts. Accordingly, shapes of the exemplary views may be modified according to manufacturing techniques and/or allowable errors. Therefore, example embodiments of inventive concepts are not limited to the specific shapes illustrated in the exemplary views, but may include other shapes that may be created according to manufacturing processes. Areas exemplified in the drawings have general properties, and are used to illustrate specific shapes of elements. Thus, this should not be construed as limited to the scope of inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings according to inventive concepts. Exemplary embodiments inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

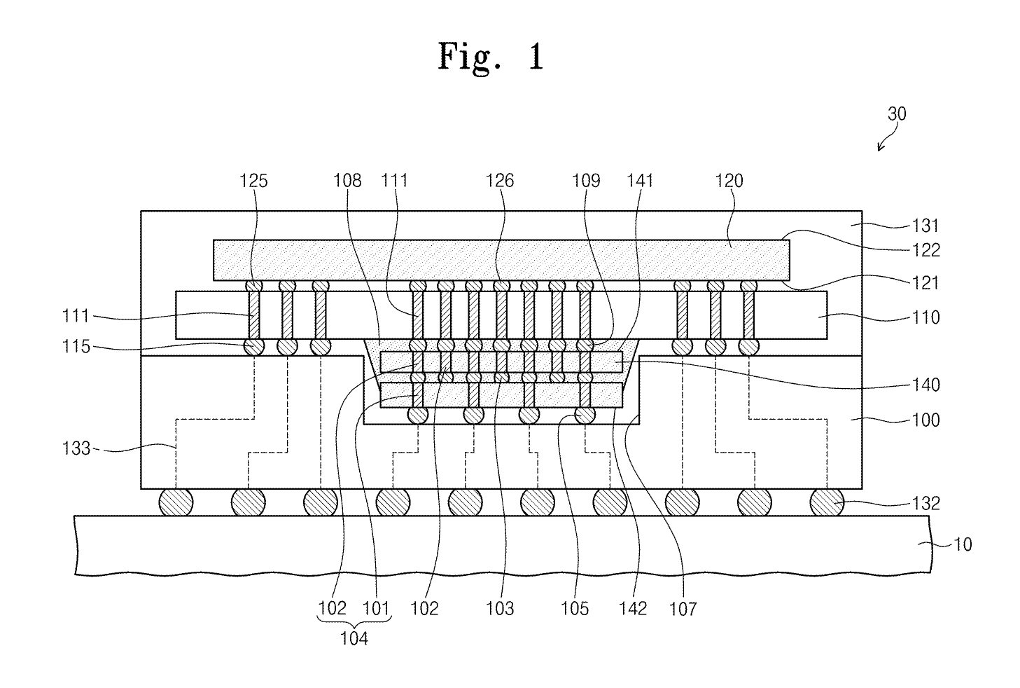

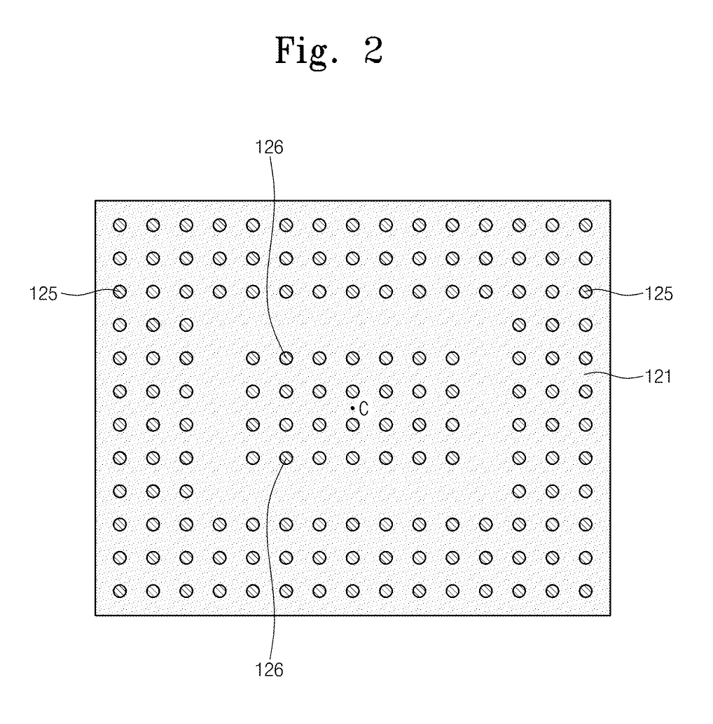

FIG. 1 is a cross sectional view illustrating a semiconductor package 30 according to example embodiments of inventive concepts and FIG. 2 is a view illustrating a bottom surface of a second semiconductor device 120 according to example embodiments of inventive concepts.

Referring to FIGS. 1 and 2, a semiconductor package 30 according to example embodiments may be provided. The semiconductor package 30 may be mounted on an external substrate 10 and may be electrically connected to the external substrate 10 through external terminals 132. For example, the external substrate 10 may be a module substrate to which a plurality of process devices may be connected. The external terminals 132 may be solder balls. Since the semiconductor package 30 is mounted on the external substrate 10, the external substrate 10 may be substantially larger than the semiconductor package 30.

The semiconductor package 30 may include a plurality of semiconductor chips. The semiconductor package 30 may include a first semiconductor device 140. The first semiconductor device 140 may include a plurality of semiconductor chips (hereinafter, referred to as ‘chips’). For example, the plurality of chips may be memory chips. However, inventive concepts are not limited thereto. Each of the plurality of chips may include an active surface 141 and a non-active surface 142 opposite to the active surface 141. The active surface 141 of each of the plurality of chips may be a face-up state to be mounted on a bottom surface of an interposer 110. The interposer 110 will be described later. For the purposes of ease and convenience in explanation, the first semiconductor device 140, including two stacked chips, will be described as an example. However, inventive concepts are not limited thereto. The first semiconductor device 140 may include more than two stacked chips. Hereinafter, an active surface 141 of the first semiconductor device 140 may be the active surface of the uppermost chip of the plurality of chips in the first semiconductor device 140, and a non-active surface 142 of the first semiconductor device 140 may be the non-active surface of the lowermost chip of the plurality of chips in the first semiconductor device 140.

First through vias 104 may penetrate at least some of the plurality of chips in the first semiconductor device 140. The first through vias 104 may be provided to each of the plurality of chips. For example, when the first semiconductor device 140 includes a first chip with a second chips on the first chip, first vias 101 may be provided to the first chip and second vias 102 may be provided to the second chip. The first vias 101 and the second vias 102 may be electrically connected to each other by internal terminals 103 to constitute current paths. Alternatively, the first via 101 may not be provided under some of the second vias 102.

The second vias 102 not connected to the first vias 101 may be paths for electrical signal transmission between the plurality of chips in the first semiconductor device 140 or paths for electrical signal transmission between the first semiconductor device 140 and a second semiconductor device 120. For example, the chips in the first semiconductor device 140 may be electrically connected to each other through the second vias 102 and the internal terminals 103. The first through vias 104 including the first vias 101 and second vias 102 will be described in more detail, hereinafter.

The second semiconductor device 120 may be provided on the first semiconductor device 140. The second semiconductor device 120 may be a logic chip.

However, inventive concepts are not limited thereto. The second semiconductor device 120 may include an active surface 121 and a non-active surface 122 opposite to the active surface 121. The active surface 121 of the second semiconductor device 120 may face the active surface 141 of the first semiconductor device 120. In other words, the first semiconductor device 140 may be disposed face to face with the second semiconductor device 120. The active surface 121 of the second semiconductor device 120 may be wider than the active surface 141 of the first semiconductor device 140.

The interposer 110 may be provided between the first and second semiconductor devices 140 and 120. The interposer 110 may not include an internal element such as a transistor, etc. The interposer 110 may include a semiconductor layer and/or an insulating layer. Second through vias 111 may penetrate the interposer 110. The second through vias 111 may be components for electrical connection of the first and second semiconductor devices 140 and 120. First terminals 105 may be formed on a bottom surface of the first semiconductor device 140. Some of the second through vias 111 may be electrically connected to the first semiconductor device 140 through second terminals 109 being formed on bottom surfaces of the some of the second through vias 111. An under-fill layer 108 may be provided between the interposer 110 and the first semiconductor device 140. The under-fill layer 108 may function to improve physical-impact and/or chemical-impact resistance characteristics. The under-fill layer 108 may include an insulating material.

The first and second semiconductor devices 140 and 120 and the interposer 110 may be mounted on the package substrate 100. For example, the package substrate 100 may be a printed circuit board (PCB). A recess region 107 may be formed in an upper portion of the package substrate 100. The first semiconductor device 140 may be provided in the recess region 107. In more detail, the first semiconductor device 140 may be electrically connected to the package substrate 100 through the first terminals 105 formed on the bottom surface of the semiconductor device 140. The first terminals 105 may be solder balls. The interposer 110 may be electrically connected to the package substrate 100 through interposer terminals 115 being formed a bottom surface of the interposer 110.

The first and second semiconductor devices 140 and 120 may be disposed in a mold layer 131. For example, the mold layer 131 may fill a space between the second semiconductor device 120 and the interposer 110, a space between the interposer 110 and the package substrate 100, and at least a portion of the recess region 107. The mold layer 131 may include an epoxy molding compound (EMC).

The external terminals 132 may be provided on a bottom surface of the package substrate 100. The semiconductor package 30 may exchange an electrical signal with the external substrate 10 through the external terminals 132 or may be applied with a voltage from the external substrate 10 through the external terminals 132.

Outer connecting terminals 125 and center connecting terminals 126 may be provided on the active surface 121 of the second semiconductor device 120. The second semiconductor device 120 may be applied with a power voltage (VDD) and/or a ground voltage (VSS) from the external substrate 10 through the connecting terminals 125 and 126, or may exchange an electrical signal with the external substrate 10 through the outer connecting terminals 125 and center connecting terminals 126.

The connecting terminals 125 and 126 may include center connecting terminals 126 overlapping with the active surface 141 of the first semiconductor device 140, and outer connecting terminals 125 formed around the center connecting terminals 126. The outer connecting terminals 125 may not overlap with the active surface 141 of the first semiconductor device 140.

For example, as illustrate in FIG. 2, the outer connecting terminals 125 may be adjacent to edges of the active surface 121 of the second semiconductor device 120 and the center connecting terminals 126 may be adjacent to a center C of the active surface 121 of the second semiconductor device 120. In FIG. 2, the outer connecting terminals 125 may be arranged along edges of the active surface 121 of the second semiconductor device 120 and the center connecting terminals 126 may be surrounded by the outer connecting terminals 125. However, inventive concepts are not limited thereto. Various arrangements of the outer and center connecting terminals 125 and 126 are possible. For example, the outer connecting terminals 125 may be formed adjacent to two edges facing each other of the active surface 121 of the second semiconductor 120 to be divided into two regions and the center connecting terminals 126 may be disposed between the two regions.

The outer connecting terminals 125 may be electrically connected to the external terminals 132 through the second through vias 111. For example, the outer connecting terminals 125 may be electrically connected to the package substrate 100 through the second through vias 111 and the interposer terminals 115, and the outer connecting terminals 125 may be electrically connected to the external terminals 132 through electrical paths 133 formed in the package substrate 100. That is, the outer connecting terminals 125 may be electrically connected to the external substrate 10 not through the first through vias 104.

The center connecting terminals 126 may be electrically connected to the external connecting terminals 132 through the first through vias 104. For example, the center connecting terminals 126 may be electrically connected to the package substrate 100 through the second through vias 111, the second terminals 109, the first through vias 104 and the first terminals 105, and the center connecting terminals 126 may be electrically connected to the external terminals 132 through the electrical paths 133 formed in the package substrate 100.

According to another exemplary embodiment of inventive concepts, when active surfaces 141 and 121 of the first and second semiconductor devices 140 and 120 are be disposed face to face, the active surface 121 of the second semiconductor device 120 being an upper layer, may be electrically connected to the active surface 141 of the first semiconductor device 140 and/or the external substrate 10, may not use through vias penetrating the second semiconductor device 120. Thus, it is possible to prevent increased size and/or cost of the semiconductor package, due at least in part, to formation of the through vias penetrating the second semiconductor device 120. However, the active surface 121 of the second semiconductor device 120 may include an overlap region, overlapping with the active surface 141 of the first semiconductor device 140 and a non-overlap region, not overlapping with the active surface 141. A path for applying a voltage signal to the overlap region from the external substrate 10 may be longer than a path for applying a voltage signal to the non-overlap region from external substrate 10. Generally, a center region of the active surface 121 of the second semiconductor device 120 may be the overlap region, overlapping with the active surface 141 of the first semiconductor device 140. Since the path for applying the voltage signal to the center region of the active surface 121 may become longer, high speed operation of the second semiconductor device 120 may be hindered.

According to example embodiments of inventive concepts, the first through vias 104 formed in the first semiconductor device 140 may be used as at least a portion of the path for applying the voltage signal to the overlap region of the active surface 121 of the second semiconductor device 120 which overlaps with the active surface 141 of the first semiconductor device 140. Thus, the path for applying the voltage signal to the second semiconductor device 120 through the center connecting terminals 126 may be reduced to smoothly apply the voltage signal to a center portion of the second semiconductor device 120. As a result, a broadband data bus may be realized.

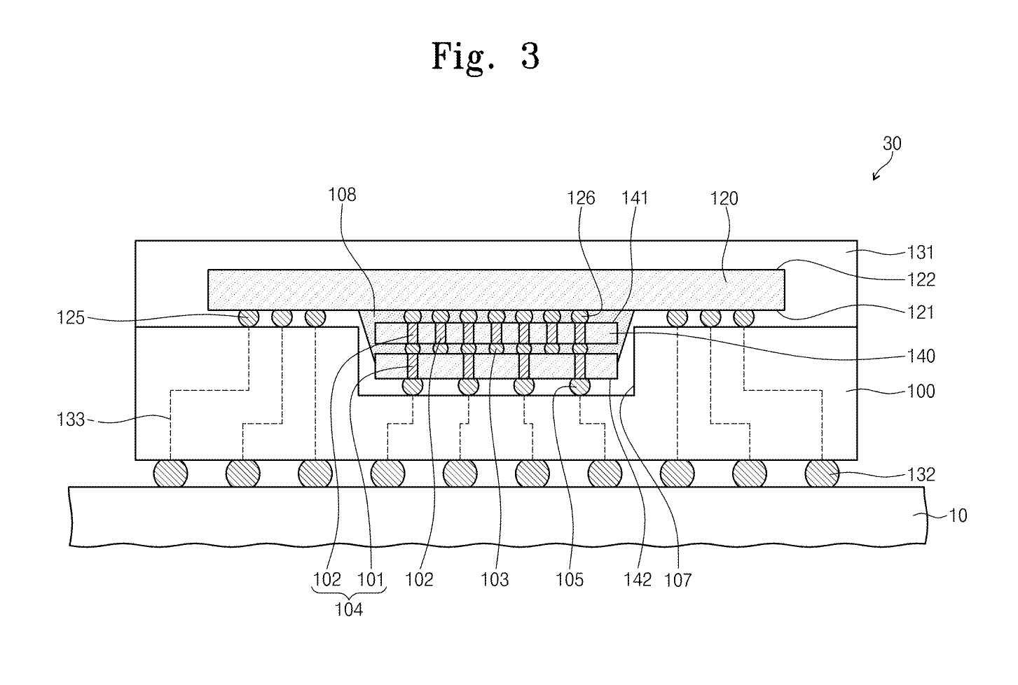

A semiconductor package according to other example embodiments of inventive concepts may be provided with reference to FIG. 3. For the purpose of ease and convenience in explanation, the descriptions to the same elements as in the above embodiment will be omitted or mentioned briefly. According to the present embodiment, the first semiconductor device 140 may be directly connected to the second semiconductor device 120 without the interposer 110, of example embodiments shown in FIG. 1. Thus, the outer connecting terminals 125 may be directly connected to the package substrate 100, and the center connecting terminals 126 may be directly connected to the first through vias 104.

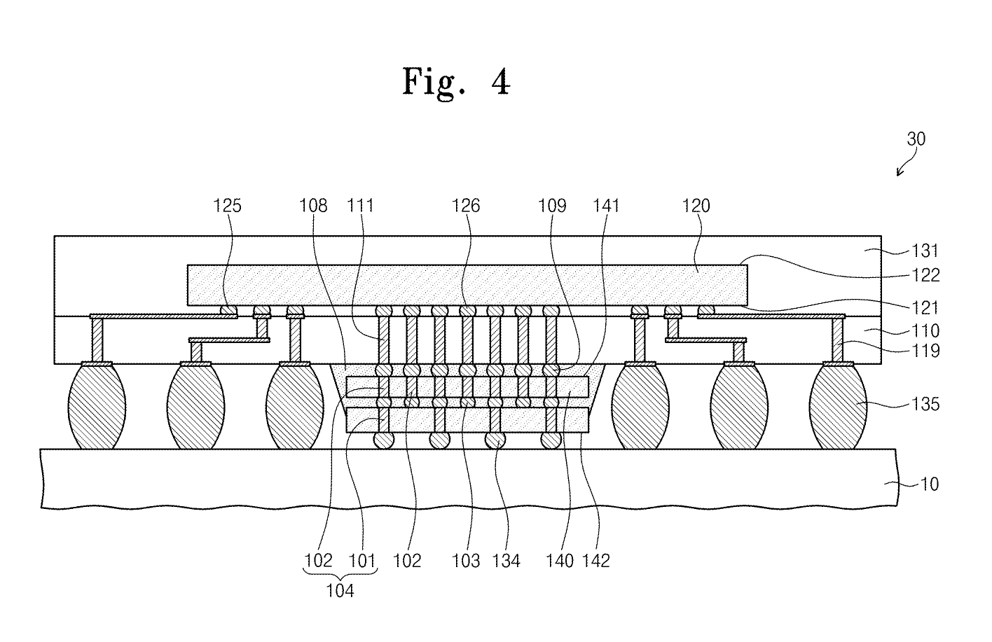

A semiconductor package according to still other example embodiments of inventive concepts may be provided with reference to FIG. 4. For the purpose of ease and convenience in explanation, the descriptions to the same elements as in the above embodiment will be omitted or mentioned briefly. According to the present embodiment, the first semiconductor device 140 and the second semiconductor device 120 may be mounted on the external substrate 10 without the package substrate. Thus, external terminals 134 and 135 may be provided on the bottom surface of the interposer 110 and the non-active surface 142 of the first semiconductor device 140. The external terminals 134 and 135 may include first external terminals 134 formed on the non-active surface 142 of the first semiconductor device 140 and second external terminals 135 formed on the bottom surface of the interposer 110. The second external terminals 135 may be electrically connected to the outer connecting terminals 125 through inner interconnections 119 formed in the interposer 110. The inner interconnections 119 may include conductive patterns and through electrodes.

The first external terminals 134 may be electrically connected to the center connecting terminals 126 through the first through vias 104. For example, the center connecting terminals 126 may be electrically connected to the first external terminals 134 through the second through vias 111, the second terminals 109, and the first through vias 104. The second external terminals 135 may be bulk bumps which are bigger than the first external terminals 134.

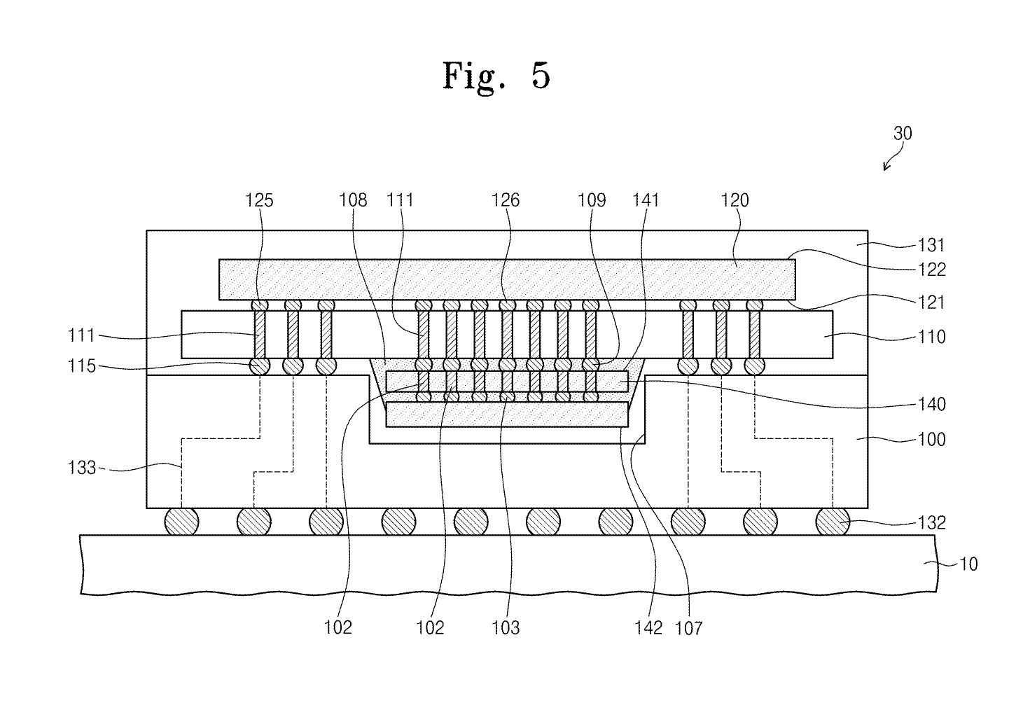

A semiconductor package according to yet other example embodiments of inventive concepts may be provided with reference to FIG. 5. For the purpose of ease and convenience in explanation, the descriptions to the same elements as in the above embodiment will be omitted or mentioned briefly. According to the present embodiment, shapes of through vias formed in the first semiconductor device 140 in FIG. 1 may be changed. In the present embodiment, the first terminal 105 and the first vias 101 illustrated in FIG. 1 may not be provided. The second vias 102 in the first semiconductor device 140 may be electrically connected between the plurality of chips in the first semiconductor device 140, or between the first semiconductor device 140 and the second semiconductor device 120.

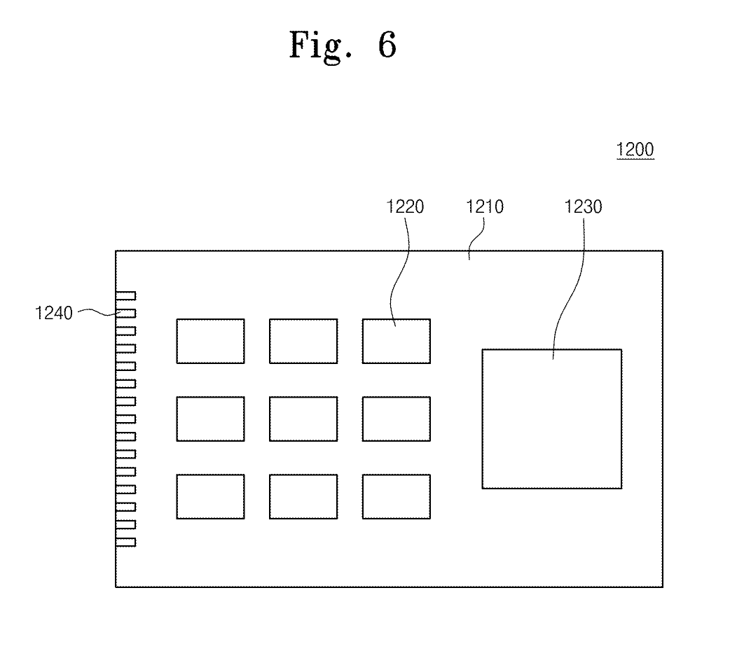

FIG. 6 is a view illustrating an example of package modules including a semiconductor package according to embodiments of inventive concepts. Referring to FIG. 6, a package module 1200 may include semiconductor integrated circuits 1220 and a semiconductor integrated circuit 1230 being packaged as a quad flat package (QFP). The semiconductor integrated circuits 1220 and 1230 to which the package technique according to inventive concepts is applied, may be mounted on a module substrate 1210, thereby forming the package module 1200. The package module 1200 may connected to an external electronic device through external connection terminals 1240.

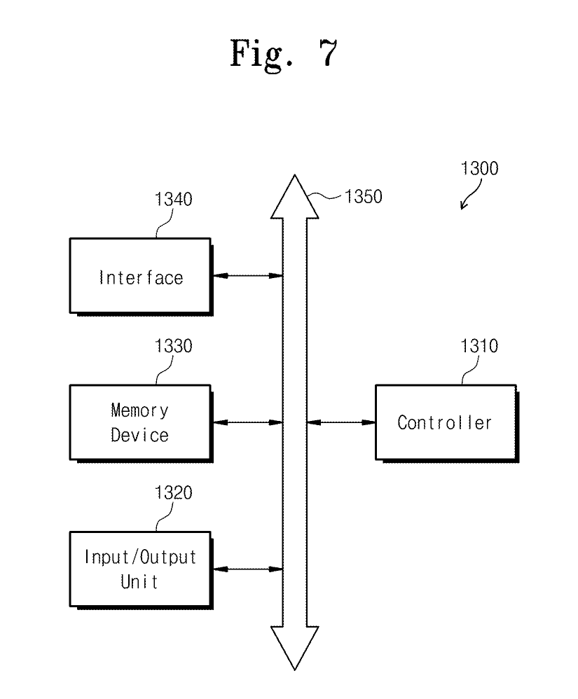

The semiconductor package technique described above may be applied to an electronic system. FIG. 7 is a schematic block diagram illustrating an example of electronic devices including a semiconductor package according to embodiments of inventive concepts. Referring to FIG. 7, an electronic system 1300 may include a controller 1310, an input/output unit 1320 and a memory device 1330. The controller 1310, the input/output unit 1320 and the memory device 1330 may be connected to each other through a bus 1350. The bus 1350 may correspond to a path through which electrical signals are transmitted. For example, the controller 1310 may include at least one of: a microprocessor, a digital signal processor, a microcontroller or another logic device. The other logic device may have a similar function to any one of the microprocessor, the digital signal processor and the microcontroller. The controller 1310 and/or the memory device 1330 may include the semiconductor package according to embodiments of inventive concepts. The input/output unit 1320 may include at least one of: a keypad, a keyboard and a display device. The memory device 1330 may be a data storage device. The memory device 1330 may store data and/or commands executed by the controller 1310. The memory device 1330 may include a volatile memory device and/or a non-volatile memory device. Or the memory device 1330 may be a flash memory. The memory device 1330 may include a solid state disk (SSD) constituted by flash memories. In this case, the electronic system 1300 may stably store mass data into the memory device 1330. The electronic system 1300 may further include an interface 1340 which may transmit data to a communication network or may receive data from a communication network. The interface 1340 may operate wirelessly or by cable. An exemplary embodiment of the interface 1340 may include an antenna for wireless communication or a transceiver for cable communication. Although not shown in the drawings, the electronic system 1300 may further include an application chipset and/or a camera image sensor (CIS).

The electronic system 1300 may be realized as a mobile system, a personal computer, industrial computer, or a logic system performing various functions. For example, the mobile system may be one of a personal digital assistant (PDA), a portable computer, a web tablet, a mobile phone, a wireless phone, a laptop computer, a memory card, a digital music player, and other electronic products. Such other electronic products may receive or transmit information data from or to the electronic system 1300. When the electronic system 1300 operates wirelessly, the electronic system 1300 may use a communication interface protocol such as third generation communication (e.g. CDMA, GSM, NADC, E-TDMA, WCDMA, CDMA2000).

According to example embodiments of inventive concepts, an electrical connection path between semiconductor devices may be reduced due to an electrical connection by through vias.

According to example embodiments of inventive concepts, when a plurality of semiconductor devices is stacked, terminals formed on a bottom surface of an upper semiconductor device of the stacked semiconductor devices may be electrically connected to an external device by through vias penetrating others of the stacked semiconductor devices. Thus, the upper semiconductor devices may be electrically connected to the external device through a shorter electrical path.

While inventive concepts have been described with reference to example embodiments, it will be apparent to those skilled in the art that various changes and modifications may be made without departing from the spirit and scope of inventive concepts. Therefore, it should be understood that the above embodiments are not limiting, but illustrative. Thus, the scope of inventive concepts is to be determined by the broadest permissible interpretation of the following claims and their equivalents, and shall not be restricted or limited by the foregoing description.

What is claimed is:

1. A semiconductor package comprising:
a first semiconductor device including an active surface and a non-active surface, the non-active surface being opposite to the active surface;
a second semiconductor device provided on the first semiconductor device, the second semiconductor device having an active surface facing the active surface of the first semiconductor device;
connection terminals on the active surface of the second semiconductor device;
first through vias in the first semiconductor device; and
external terminals providing electrical connection with an external device,
wherein the connection terminals comprise:
center terminals overlapping with the active surface of the first semiconductor device; and
outer terminals around the center terminals,
wherein the center terminals are electrically connected to the external terminals through the first through vias.

2. The semiconductor package of claim 1, wherein
the outer terminals are electrically connected to the external terminals not through the first through vias.

3. The semiconductor package of claim 1, further comprising:
a package substrate between the first semiconductor device and the external terminals, wherein
the external terminals are provided on a bottom surface of the package substrate.

4. The semiconductor package of claim 3, wherein
the first semiconductor device is provided in a recess region formed in an upper portion of the package substrate.

5. The semiconductor package of claim 1, wherein the external terminals include:
first external terminals provided on a bottom surface of the first semiconductor device, the first external terminals configured to be connected to the first through vias; and
second external terminals electrically connected to the outer terminals.

6. The semiconductor package of claim 5, wherein
each of the second external terminals is greater in volume than each of the first external terminals.

7. The semiconductor package of claim 6, further comprising:
an interposer between the first semiconductor device and the second semiconductor device,
wherein the second external terminals are provided on a bottom surface of the interposer.

8. The semiconductor package of claim 1, further comprising:
an interposer between the first semiconductor device and the second semiconductor device; and
second through vias penetrating the interposer,
wherein the outer terminals are electrically connected to the external terminals through some of the second through vias; and
wherein the center terminals are electrically connected to the first through vias through others of the second through vias.

9. The semiconductor package of claim 1, further comprising:
first terminals provided on a bottom surface of the first semiconductor device,
wherein some of the first through vias are not electrically connected to the first terminals.

10. The semiconductor package of claim 1, wherein the active surface of the second semiconductor device is wider than the active surface of the first semiconductor device.

11. The semiconductor package of claim 1, wherein the center terminals provide a power voltage or a ground voltage to the second semiconductor device from the external device.

12. A semiconductor package comprising:
a first semiconductor device;
a second semiconductor device on the first semiconductor device;
connection terminals provided on a bottom surface of the second semiconductor device;
first through vias provided in the first semiconductor device; and
external terminals providing electrical connection with an external device,
wherein some of the connection terminals are electrically connected to the first through vias; and
wherein others of the connection terminals are electrically connected to the external terminals not through the first through vias.

13. The semiconductor package of claim 12, wherein an active surface of the first semiconductor device and an active surface of the second semiconductor device face each other.

14. The semiconductor package of claim 13, further comprising:
an interposer disposed between the first and second semiconductor devices, the interposer including second through vias,
wherein the connection terminals are electrically connected to the second through vias.

15. The semiconductor package of claim 13, further comprising:
an interposer disposed between the first and second semiconductor devices, the interposer including second through vias,
wherein some of the connection terminals are electrically connected to the second through vias.

16. The semiconductor package of claim 12, further comprising:
an interposer disposed between the first and second semiconductor devices, the interposer including second through vias,
wherein the connection terminals are electrically connected to the second through vias.

17. The semiconductor package of claim 12, wherein the first through vias electrically connect the connection terminals to the external terminals.

18. The semiconductor package of claim 12, wherein some of the first through vias electrically connect the connection terminals to the external terminals.

19. The semiconductor package of claim 12, further comprising:
an interposer disposed between the first and second semiconductor devices, the interposer including second through vias,
wherein some of the connection terminals are electrically connected to the second through vias.
